(19) United States
(12) Patent Application Publication
(10) Pub. No.: US 2008/0003829 A1
(43) Pub. Date: Jan. 3, 2008

(54) Chemical mechanical polishing slurry

(76) Inventors: Dong Mok Shin, Daejeon (KR); Eun Mi Choi, Daejeon (KR); Seung Beom Cho, Daejeon (KR)

Correspondence Address: Song K. Jung;MCKENNA LONG & ALDRIDGE LLP, 1900 K Street, N.W., Washington, DC, 20006, US

(21) Appl. No.: 11/819,942

(22) Filed: Jun. 29, 2007

(30) Foreign Application Priority Data
Jun. 30, 2006 (KR) 2006-60807

(51) Int. Cl. H01L 21/461; C03C 15/00; C09K 13/00

(52) U.S. Cl. 438/692; 438/693; 216/89; 252/79.1

(57) ABSTRACT

Disclosed is chemical mechanical polishing (CMP) slurry comprising: abrasive particles; an oxidant; a compound having at least two amine groups; a polycarboxylic acid; and water. The CMP slurry comprising a compound having at least two amine groups and a polycarboxylic acid provides an improved removal rate and selectivity of copper, while not adversely affecting the overall polishing rate, increases the planarization, and minimizes dishing and erosion problems.

This application claims the benefit of the filing date of Korean Patent Application No. 10-2006-0060807, filed on Jun. 30, 2006, in the Korean Intellectual Property Office, the disclosure of which is incorporated herein in its entirety by reference.

### BACKGROUND OF THE INVENTION

(a) Field of the Invention

The present invention relates to chemical mechanical polishing (CMP) slurry. More particularly, the present invention relates to CMP slurry using a compound having at least two amine groups to improve the removal rate and selectivity of copper and comprising a polycarboxylic acid to increase the planarization degree (delta uniformity) during polishing.

(b) Description of the Related Art

In general, there has been a tendency to increase the diameter of a wafer in current semiconductor fabrication processes so as to accomplish high integration of an ULSI (ultralarge scale integrated circuit). Also, current semiconductor fabrication has been subjected to stricter standards including the minimum line width requirement of 0.13 μm or less. Further, a multilayer interconnection structure is an essential element for improving the performance of a semiconductor device.

When forming a multilayer interconnection, a planarization step for one layer is required for the subsequent layer. Planarization by conventional technologies, including reflow, SOG (spin on glass) or etchback cannot provide a sufficient result as the number of the interconnection layers increases and the minimum line width reduces. Thus, chemical mechanical polishing technique has been suggested. CMP is the technology including the steps of embedding interconnection materials, such as tungsten, aluminum or copper, into holes or grooves formed in a dielectric on a process wafer, and removing a surplus amount of the interconnection materials via polishing to perform interconnection. In this technology, an aqueous dispersion comprising abrasive particles formed of silica, alumina or a metal oxide has been used to date as a polishing agent. However, such particles have high hardness and cause problems, such as scratches, dishing or erosion, resulting in a drop in the reliability of a circuit on a surface to be polished.

To solve the above problems, AFP (abrasive-free polishing) using no abrasive particles has been reported. It is also known that the use of a suitable corrosion inhibitor can reduce dishing. However, AFP or the use of a corrosion inhibitor is problematic in that the polishing rate is significantly reduced. Under these circumstances, there has been a continuous need for a novel method for reducing dishing and erosion problems while providing a high polishing rate.

### SUMMARY OF THE INVENTION

Therefore, the present invention has been made in view of the above-mentioned problems. It is an object of the present invention to provide CMP slurry that improves the removal rate and selectivity of copper, increases the planarization degree (delta uniformity) during polishing, thus reducing various problems that may occur during the polishing, including dishing and erosion.

In order to achieve the above-mentioned object, there is provided CMP slurry comprising: abrasive particles; an oxidant; a compound having at least two amine groups; a polycarboxylic acid; and water.

More particularly, the CMP slurry comprises: 0.1˜30 wt % of abrasive particles: 0.1˜10 wt % of an oxidant; 0.05˜2 wt % of a compound having at least two amine groups; 0.01˜1 wt % of a polycarboxylic acid; and the balance amount of water, based on 100 wt % of the total slurry.

Additionally, there is provided a chemical mechanical polishing (CMP) method for planarizing a metal layer, an oxide layer, an interlayer dielectric or a metal interconnection by using CMP slurry according to the present invention.

It may be considered that CMP for copper interconnection is performed in such a manner that the overpolishing time is reduced in order to reduce the problems of dishing and erosion. Herein, reduction of the overpolishing time is allowed when the surface to be polished shows global planarization and polishing selectivity of a copper layer to a barrier metal layer and an interlayer dielectric is high. If the polishing selectivity is low, a local increase in the polishing rate occurs at portions with a high pattern density, resulting in generation of defects, including erosion.

Therefore, the CMP slurry, particularly for CMP slurry for copper interconnection, according to the present invention uses a compound having at least two amine groups to increase the removal rate and selectivity of a copper layer, and comprises a polycarboxylic acid to increase the degree of planarization (delta uniformity) during the polishing, so that the problems occurring in conventional polishing processes can be solved.

### DETAILED DESCRIPTION OF THE INVENTION

Hereinafter, the present invention will be explained in more detail.

According to a preferred embodiment of the present invention, the abrasive particles include metal oxides, organic particles or organic-inorganic composite particles. As the metal oxide particle, at least one particle selected from the group consisting of silica (SiO₂), alumina (Al₂O₃), ceria (CeO₂), zirconia (ZrO₂) and titania (titanium dioxide) may be used. Such metal oxide particles may be obtained via any one process of a fuming process and a sol-gel process. Particularly, silica is preferred.

Primary particles of such abrasive particles preferably have a size of 10˜200 nm, and more preferably 20˜100 nm. If the particles are too small, the polishing rate decreases. If the particles are too large, dispersion stability decreases.

The abrasive particles are used in an amount of 0.1˜30 wt %, and preferably of 1˜10 wt % based on the total weight of the slurry. If the amount of the abrasive particles is less than 0.1 wt %, it is not possible to perform polishing sufficiently, resulting in a drop in the polishing selectivity. If the amount of the abrasive particles is greater than 30 wt %, the resultant slurry shows low stability.

Chemical mechanical polishing using the CMP slurry according to the present invention is based on the repetitive mechanism, including oxidizing an interconnection metal to form an oxide layer and removing the oxide layer via chemical/physical polishing actions. Thus, an oxidant is required to form the oxide layer. Non-limiting examples of the oxidant that may be used in the present invention include hydrogen peroxide, organic peroxide, ammonium persulfate (APS), potassium persulfate (KPS), hypochlorous acid (HOCl), potassium permanganate, ferric nitrate, potassium ferricyanide, potassium periodinate, sodium hyperchlorite (NaOCl), vanadium trioxide, potassium bromate (KBrO₃), or the like. Non-limiting examples of the organic peroxide that may be used in the present invention include peracetic acid, perbenzoic acid, t-butylhydroperoxide, or the like. Such oxidants may be used alone or in combination, and hydrogen peroxide is particularly preferred.

The oxidant is used in an amount of 0.1˜10 wt %, and preferably of 0.1˜5 wt %, based on the total weight of the slurry. If the amount of the oxidant is greater than 10 wt %, excessive surface corrosion or local corrosion occurs. If the amount of the oxidant is less than 0.1 wt %, the polishing rate decreases significantly.

In order to remove metal ions by forming a complex with the oxidized metal ions as well as to increase the polishing rate, the CMP slurry according to the present invention uses a compound having at least two amine groups as a complexing agent (ligand). In general, metal ions form a complex with ligands having electron pairs shared by the metal ions, and the complex formed thereby has a stable structure and cannot be redeposited easily onto a metal surface.

Meanwhile, a multidentate ligand has a chelating effect followed by a significant increase in the complex formation coefficient, as compared to a monodentate ligand. Therefore, a multidentate ligand having at least two binding sites may be used as the complexing agent. As the multidentate ligand, a compound having at least two amine groups is preferred, and a diamine derivative is more preferred. Preferably, each amine group in the compound having at least two amine groups is a primary amine group.

Non-limiting examples of the compound having at least two amine groups include ethylene diamine, 1,2-diaminocyclohexane, diaminopropionic acid, 1,2-diaminopropane, 1,3-diamiopropane, diaminopropanol, diethylene triamine, 2-(aminomethyl)propane-1,3-diamine, or the like. Such compounds may be used alone or in combination. Among the above compounds, ethylene diamine is preferred.

The compound having at least two amine groups is used in an amount of 0.05˜2 wt %, and preferably of 0.1˜1 wt % based on the total weight of the slurry. If the amount of the compound is greater than 2 wt %, excessive surface corrosion occurs and WIWNU (Within Wafer Non-Uniformity) is significantly deteriorated. If the amount of the compound is less than 0.1 wt %, it is not possible to obtain a desired effect.

Meanwhile, the compound having at least two amine groups may be used in combination with another complexing agent so as to control the stability and polishing rate. Herein, such complexing agents that may be used in combination with the compound having at least two amine groups include amino acid compounds and carboxylic acid compounds, and particular examples thereof include alanine, glycine, cystine, histidine, asparagine, maleic acid, malic acid, tartaric acid, citric acid, malonic acid, phthalic acid, acetic acid, lactic acid, oxalic acid and salts thereof. The above compounds may be used alone or in combination. Glycine is particularly preferred.

The amino acid compound and/or the carboxylic acid compound functioning as a complexing agent is used in an amount of 0.05˜2 wt %, and preferably of 0.1˜1 wt % based on the total weight of the slurry.

The CMP slurry according to the present invention comprises a polycarboxylic acid in order to accomplish the global planarization of the surface to be polished. The polycarboxylic acid may also serve to improve the dispersion stability of the polishing agent.

Non-limiting examples of the polycarboxylic acid include polyacrylic acid, acrylic acid-maleic acid copolymer, acrylic acid-ethylene copolymer, acrylic acid-acrylamide copolymer and salts thereof. The polycarboxylic acid compounds have an average molecular weight of 1,000˜1,000,000, and preferably of 1,000˜500,000. The polycarboxylic acid compounds may be used alone or in combination in a solid form or as an aqueous solution.

The polycarboxylic acid is used preferably in an amount of 0.01˜1 wt % based on the total weight of the slurry. Even if the amount of the polycarboxylic acid is greater than 1 wt %, any additional effect of improving the planarization of the surface to be polished cannot be obtained. On the contrary, if the amount of the polycarboxylic acid is less than 0.01 wt %, it is not possible to improve the planarization of the surface to be polished and dispersion stability of the polishing agent sufficiently.

Meanwhile, the CMP slurry according to the present invention may further comprise a pH modifier to adjust the pH to an applicable range. Non-limiting examples of the pH modifier include: basic modifiers, such as potassium hydroxide, sodium hydroxide, aqueous ammonia, rubidium hydroxide, cesium hydroxide, sodium hydrogen carbonate, etc.; and acidic modifiers, such as hydrochloric acid, nitric acid, sulfuric acid, phosphoric acid, formic acid, acetic acid, etc. When using a strong acid or strong base, particle agglomeration may occur in the slurry due to a local pH change. Thus, such strong acids or bases are used preferably after diluting them with deionized water.

Herein, the pH modifier is preferably used in such a manner that the CMP slurry according to the present invention has a pH of 8˜10. CMP slurry having a pH of less than 8 or greater than 10 may adversely affect the removal rate and selectivity.

Also, the present invention provides a chemical mechanical polishing (CMP) method using the CMP slurry according to the present invention for carrying out planarization of metal layers, oxide layers, interlayer dielectrics or metal interconnections. The CMP method may be performed in a conventional manner known to one skilled in the art except the use of the CMP slurry according to the present invention, and thus detailed description of the CMP method will be omitted herein.

Reference will now be made in detail to the preferred embodiments of the present invention. It is to be understood that the following examples are illustrative only and the present invention is not limited thereto.

The silica used in the following example is commercially available from Fuso Chemical Co., Ltd., as the trade name of PL-3L (primary particle diameter: 35 nm) of the Quartron PL series.

### EXAMPLE 1

To a polypropylene bottle, 2 wt % of colloidal silica (PL-3L), 0.25 wt % of glycine, 0.25 wt % of EDA (ethylene diamine), 1 wt % of hydrogen peroxide and 0.5 wt % of polyacrylic acid having an average molecular weight of 2,000 were introduced, based on 100 wt % of the combined weight thereof. Next, deionized water was added to the mixture, the pH of the mixture was adjusted to 9, and the mixture was agitated for 10 minutes under a high speed. The resultant slurry was used for polishing for 1 minute under the following conditions. The removal rate was determined by measuring the variation in the thickness before and after polishing. The results are shown in the following Table 1.

[Polishing Conditions]

Polishing system: CDP 1CM51 (Logitech Co.)

Polishing pad: IC1000/SubaIV Stacked (Rodel Co.)

Platen speed: 75 rpm

Carrier speed: 75 rpm

Pressure: 5 psi

Slurry flow rate: 200 ml/min.

[Objects to be Polished]

A 6-inch copper (Cu) wafer on which a Cu layer is deposited to 15,000 Å via PVD (physical vapor deposition)

A 6-inch tantalum (Ta) wafer on which a Ta layer is deposited to 3,000 Å via PVD (physical vapor deposition)

A 6-inch silicon oxide (SiO₂) wafer on which a SiO₂ layer is deposited to 7,000 Å from PETEOS (plasma-enhanced tetraethylorthosilicate)

[Evaluation]

The thickness of each metal layer was measured by using LEI1510 Rs Mapping system (LEI Co.) from the surface resistance of each layer according to the following formulae:

[Cu layer thickness (Å)] [Cu layer resistivity (Ω/cm)/sheet resistivity (Ω/□)]×10⁸

[Ta layer thickness (Å)]=[Ta layer resistivity (Ω/cm)/sheet resistivity (Ω/□)]×10⁸

The thickness of the TEOS layer was measured by using an optical thickness measuring system, i.e. Nanospec 6100 (Nanometrics Co.).

Delta uniformity during the polishing of the Cu layer was calculated according to the following formula:

[Delta Uniformity (%)]=[(standard deviation in polishing amount)/(average polishing amount)]×100

### EXAMPLES 2˜5

Polishing slurry was prepared by using the corresponding additives and pH index as shown in the following Table 1 in a similar manner to Example 1. Polishing and evaluation were performed in the same manner as described in Example 1. The results are shown in the following Table 1.

### COMPARATIVE EXAMPLES 1˜5

Polishing slurry was prepared by using the corresponding additives and pH index as shown in the following Table 2 in a similar manner to Example 1. Polishing and evaluation were performed in the same manner as described in Example 1. The results are shown in the following Table 2.

TABLE 1

| | | Example | | | | |
|---|---|---|---|---|---|---|
| | | 1 | 2 | 3 | 4 | 5 |
| Abrasive (wt %) | | PL3L (2) | PL3L (2) | PL3L (2) | PL3L (2) | PL3L (2) |
| Oxidizing Agent | | H₂O₂ | H₂O₂ | H₂O₂ | H₂O₂ | APS (5) |
| (wt %) | | (0.5) | (0.5) | (0.5) | (0.5) | |
| Amine Compound | | EDA | EDA | EDA | EDA | PDA |
| (wt %) | | (0.25) | (0.25) | (0.5) | (0.25) | (0.25) |
| Complexing Agent | | Glycine | Glycine | — | Glycine | Glycine |
| (wt %) | | (0.25) | (0.25) | | (0.25) | (0.25) |
| Corrosion | | — | — | — | — | — |
| Inhibitor (wt %) | | | | | | |
| Polycarboxylic acid | | PAA | PAA-MA | PAA | PAA | PAA |
| (wt %) | | Mw. 2000 | Mw. 5000 | Mw. 2000 | Mw. 250,000 | Mw. 2000 |
| | | (0.5) | (0.2) | (0.5) | (0.2) | (0.5) |
| pH | | 9 | 9 | 9 | 9 | 7.7 |
| Removal | Cu | 3918 | 4105 | 4277 | 3257 | 2545 |
| Rate | Ta | 35 | 41 | 30 | 27 | 516 |
| (Å/min) | Oxide | 46 | 33 | 35 | 17 | 110 |
| Delta Uniformity (%) | | 5.2 | 5.6 | 5.9 | 4.9 | 5.0 |
| Selectivity | Cu/Ta | 112 | 100 | 143 | 121 | 5 |
| | Cu/Ox | 85 | 124 | 122 | 192 | 23 |

*EDA: ethylene diamine
*PDA: 1,2-diaminopropane
*PAA: polyacrylic acid
*PAA-MA: acrylic acid-maleic acid copolymer

TABLE 2

| | | Comparative Example | | | | |
|---|---|---|---|---|---|---|
| | | 1 | 2 | 3 | 4 | 5 |
| Abrasive (wt %) | | PL3L (5) | PL3L (8) | PL3L (2) | PL3L (2) | PL3L (2) |
| Oxidizing Agent | | H₂O₂ (1) | H₂O₂ (1) | APS (1) | H₂O₂ (1) | H₂O₂ |
| (wt %) | | | | | | (0.5) |
| Amine Compound | | — | — | — | EDA | — |
| (wt %) | | | | | (0.25) | |
| Complexing Agent | | Glycine | Maleic | Glycine | Glycine | Glycine (0.5) |
| (wt %) | | (0.5) | Acid (1) & | (1) | (0.25) | |
| | | | Glycine | | | |
| | | | (0.25) | | | |
| Corrosion | | — | BTA | — | — | — |
| Inhibitor (wt %) | | | (0.2) | | | |
| Polycarboxylic | | — | — | — | — | PAA |
| acid (wt %) | | | | | | Mw. 2000 |
| | | | | | | (0.5) |
| pH | | 9 | 9.5 | 9.14 | 9 | 9 |
| Removal | Cu | 3014 | 203 | 1112 | 5255 | 2780 |
| Rate | Ta | 132 | 163 | 670 | 91 | 169 |
| (Å/min) | Oxide | 99 | 206 | 87 | 31 | 75 |
| Delta Uniformity (%) | | 8.8 | 11.9 | 15.4 | 15.2 | 5.5 |
| Selectivity | Cu/Ta | 23 | 1 | 2 | 58 | 16 |
| | Cu/Ox | 30 | 1 | 13 | 170 | 37 |

As can be seen from Tables 1 and 2, the polishing slurry (Examples 1˜5) comprising a compound having at least two amine groups, such as EDA, provides a significantly increased Cu removal rate and a sufficiently high Cu/Ta or Cu/oxide selectivity, as compared to the polishing slurry (Comparative Examples 1 and 3) using no compound having at least two amine groups and comprising glycine alone or the polishing slurry (Comparative Example 2) comprising a carboxylic acid and glycine.

Additionally, the polishing slurry (Comparative Examples 1˜4) using no polycarboxylic acid, such as PAA or PAA-MA, provides a low delta uniformity. However, the slurry (Examples 1˜5) comprising a polycarboxylic acid provides an improved delta uniformity.

Meanwhile, the polishing slurry (Comparative Example 5) using no compound having at least two amine groups and comprising glycine and PAA provides a similar delta uniformity as compared to the delta uniformity of the slurry according to Examples 1˜4. However, the slurry according to Examples 1˜4 provides an excellent Cu removal rate as well as excellent Cu/Ta and Cu/oxide polishing selectivity as compared to the slurry according to Comparative Example 5. Therefore, it can be seen from the above results that the CMP slurry comprising a compound having at least two amine groups, such as EDA, provides a significantly improved Cu removal rate and polishing selectivity.

As can be seen from the foregoing, the CMP slurry comprising a compound having at least two amine groups and a polycarboxylic acid according to the present invention provides an improved removal rate and selectivity of copper, while not adversely affecting the overall polishing rate, increases the degree of planarization (delta uniformity), and minimizes dishing and erosion problems.

Although several preferred embodiments of the present invention have been described for illustrative purposes, those skilled in the art will appreciate that various modifications, additions and substitutions are possible without departing from the scope and spirit of the invention as disclosed in the accompanying claims.

What is claimed is:

1. A Chemical mechanical polishing (CMP) slurry comprising: abrasive particles; an oxidant; a compound having at least two amine groups; a polycarboxylic acid; and water.

2. The CMP slurry as claimed in claim 1, which comprises: 0.1˜30 wt % of abrasive particles: 0.1˜10 wt % of an oxidant; 0.05˜2 wt % of a compound having at least two amine groups; 0.01˜1 wt % of a polycarboxylic acid; and the balance amount of water, based on 100 wt % of the total slurry.

3. The CMP slurry as claimed in claim 1, wherein the abrasive particles include metal oxides, organic particles or organic-inorganic composite particles.

4. The CMP slurry as claimed in claim 1, wherein the abrasive particle is at least one particle selected from the group consisting of silica (SiO₂), alumina (Al₂O₃), ceria (CeO₂), zirconia (ZrO₂) and titania (titanium dioxide).

5. The CMP slurry as claimed in claim 1, wherein the abrasive particles have a primary particle size of 10˜200 nm.

6. The CMP slurry as claimed in claim 1, wherein the oxidant is at least one compound selected from the group consisting of hydrogen peroxide, organic peroxide, ammonium persulfate (APS), potassium persulfate (KPS), hypochlorous acid (HOCl), potassium permanganate, ferric nitrate, potassium ferricyanide, potassium periodinate, sodium hyperchlorite (NaOCl), vanadium trioxide, potassium bromate (KBrO₃), peracetic acid, perbenzoic acid, and t-butyl hydroperoxide.

7. The CMP slurry as claimed in claim 1, wherein the compound having at least two amine groups is at least one compound selected from the group consisting of ethylene diamine, 1,2-diaminocyclohexane, diaminopropionic acid, 1,2-diaminopropane, 1,3-diamiopropane, diaminopropanol, diethylene triamine, and 2-(aminomethyl)propane-1,3-diamine.

8. The CMP slurry as claimed in claim 1, which further comprises at least one complexing agent selected from the group consisting of amino acid compounds and carboxylic acid compounds.

9. The CMP slurry as claimed in claim 8, wherein the complexing agent is used in an amount of 0.05˜2 wt % in the CMP slurry.

10. The CMP slurry as claimed in claim 8, wherein the amino acid compounds and the carboxylic acid compounds include alanine, glycine, cystine, histidine, asparagine, maleic acid, malic acid, tartaric acid, citric acid, malonic acid, phthalic acid, acetic acid, lactic acid, oxalic acid and salts thereof.

11. The CMP slurry as claimed in claim 1, wherein the polycarboxylic acid has an average molecular weight of 1,000˜1,000,000, and is at least one compound selected from the group consisting of polyacrylic acid, acrylic acid-maleic acid copolymer, acrylic acid-ethylene copolymer, acrylic acid-acrylamide copolymer and salts thereof.

12. The CMP slurry as claimed in claim 1, which is for use in polishing copper interconnections.

13. The CMP slurry as claimed in claim 1, which has a pH modified to a range of 8˜10.

14. A chemical mechanical polishing (CMP) method for planarizing a metal layer, an oxide layer, an interlayer dielectric or a metal interconnection by using CMP slurry comprising: abrasive particles; an oxidant; a compound having at least two amine groups; a polycarboxylic acid; and water.

15. The CMP method as claimed in claim 14, wherein the CMP slurry comprises: 0.1˜30 wt % of abrasive particles: 0.1˜10 wt % of an oxidant; 0.05˜2 wt % of a compound having at least two amine groups; 0.01˜1 wt % of a polycarboxylic acid; and the balance amount of water, based on 100 wt % of the total slurry.

16. The CMP method as claimed in claim 14, wherein the CMP slurry further comprises at least one complexing agent selected from the group consisting of amino acid compounds and carboxylic acid compounds.

17. The CMP method as claimed in claim 16, wherein the complexing agent is used in an amount of 0.05˜2 wt % in the CMP slurry.
